(19) United States
(12) Patent Application Publication
(10) Pub. No.: US 2008/0267322 A1
(43) Pub. Date: Oct. 30, 2008

(54) SYSTEM AND METHOD FOR TRELLIS CONSTRUCTION FOR GOUP CODES

(76) Inventors: Manik Raina, Bangalore (IN); Ranjeet Patro, Bangalore (IN); Chandrashekhara PS Thejaswi, Tempe, AZ (US); Viswanath Ganapathy, Bangalore (IN)

Correspondence Address: SCHWEGMAN, LUNDBERG & WOESSNER, P.A., P.O. BOX 2938, MINNEAPOLIS, MN, 55402, US

(21) Appl. No.: 12/106,041

(22) Filed: Apr. 18, 2008

Related U.S. Application Data
(60) Provisional application No. 60/925,047, filed on Apr. 18, 2007.

(51) Int. Cl. H04L 27/06; H03M 13/23; G06F 11/08

(52) U.S. Cl. 375/341; 714/792; 714/E11.031

(57) ABSTRACT

A method and system constructs a minimal trellis for decoding a block group code. A generator matrix of the code is obtained and converted into a row-reduced echelon matrix form. Vertices are determined from the row-reduced echelon matrix form at a first time. Further vertices at later times are also determined to obtain a minimal trellis for the block group code C for storing or use in decoding received codes.

### CLAIM OF PRIORITY

This patent application claims the benefit of priority, under 35 U.S.C. Section 119(e) to U.S. Provisional Patent Application Ser. No. 60/925,047, entitled “System and Method for Trellis Construction for Group Codes”, filed on Apr. 18, 2007, which is incorporated herein by reference in its entirety.

### BACKGROUND

In many communication systems, codes are used to represent data during transmission of the data. The codes may have some built in redundancy in order to ensure communications are properly received. Several things may interfere with transmission, and the amount of redundancy built into various codes may vary to ensure proper reception in different settings. For instance, noise may be more prevalent in industrial settings, and it may be more important for the information to be properly received. In such a setting, a higher redundancy code may be used for transmission. Signals may also travel on multiple paths, and multiple signals from different transmissions may be mixed in with the codes being transmitted. All these factors may be taken into account when selecting codes during design of a communication system.

Block group codes are widely used in block-coded modulation schemes. The construction of these codes is important because if sets with more than two signals are used for transmission, then group structures (rather than field-like structures) match the relevant distance measure of a given channel.

Since the full potential of block-coded modulation schemes may be achieved by using soft-decision decoding, Trellis based decoding becomes very attractive for block group codes.

A Trellis is an edge labeled graph. In such a graph, there exists a pair of vertices called the root and toor, at which the Trellis commences and terminates. These are the leftmost and the rightmost vertices respectively. Each path from the root vertex to the toor vertex represents a valid codeword in the code which the Trellis represents. To get the codewords, the labels of the edges of a path are concatenated.

The Trellis of a code is used for soft-decision decoding of linear or rectangular codes. Trellises permit Maximum-likelihood (ML) decoding. In this type of decoding, the codewords of the code which are most likely to have been transmitted are determined, given the codeword (possibly distorted by noise) which was received is known. The parameters of the Trellis (like the number of vertices) of a block group code determine the complexity of decoding. Therefore considerable work has been done on constructing minimal trellises for block codes.

Various trellis construction techniques are known for codes over finite fields, including a Massey and a BCJR approach. KS (Kalman smoother) construction has been described for a minimal trellis construction approach for block codes over finite abelian groups.

### BRIEF DESCRIPTION OF THE DRAWINGS

FIG. 1 is a representation of a minimal Massey trellis for a code according to an example embodiment.

FIG. 2 is a pseudo code representation of a method of generating a row-reduced echelon generator matrix according to an example embodiment.

FIG. 3 is a pseudo code representation of a method of generating a minimal trellis using a BCJR technique for a code of length n according to an example embodiment.

FIG. 4 is a representation of a minimal BCJR trellis for a code according to an example embodiment.

FIG. 5 is a pseudo code representation of a method of determining the number of vertices in a minimal trellis for a code C according to an example embodiment.

FIG. 6 is a pseudo code representation of a method of determining the number of edges in a minimal trellis for code C according to an example embodiment.

FIG. 7 is a pseudo code representation of an alternative method of determining the number of edges in a minimal trellis for code C according to an example embodiment.

FIG. 8 is a flowchart of a method of generating a Massey trellis according to an example embodiment.

FIG. 9 is a block diagram of a system for generating a Massey trellis according to an example embodiment.

FIG. 10 is a flowchart of a method of generating a BCJR trellis according to an example embodiment.

FIG. 11 is an example embodiment of a computer system for performing the methods and algorithms according to example embodiments.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software or a combination of software and human implemented procedures in one embodiment. The software may consist of computer executable instructions stored on computer readable media such as memory or other type of storage devices. The term “computer readable media” is also used to represent any means by which the computer readable instructions may be received by the computer, such as by different forms of wired or wireless transmissions. Further, such functions correspond to modules, which are software, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system.

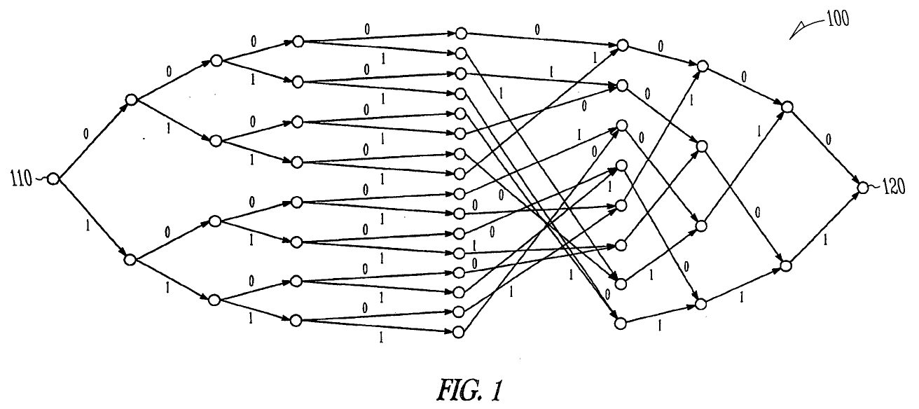

A Trellis is an edge labeled graph 100, as shown in FIG. 1. In such a graph, there exists a pair of vertices called the root vertex 110 and toor vertex 120, at which the Trellis commences and terminates. These are the leftmost and the rightmost vertices respectively. Each path from the root vertex 110 to the toor 120 represents a valid codeword in the code which the Trellis 100 represents. To get the codewords, the labels of the edges of a path are concatenated.

A Massey and BCJR approach for minimal trellis construction for codes over finite abelian groups is described in some embodiments. Constructing a Massey trellis is described given the generator matrix of the code. The BCJR approach for trellis construction utilizes a parity check matrix of the code. Proof of minimality of the construction and discussion of the algorithmic complexities of these techniques is also offered. Concrete examples are provided for both approaches.

The description is organized in the following manner. A brief introduction on block codes over finite abelian groups is first provided. The Massey approach for trellis construction and the minimality of the approach is also provided. Given a parity check matrix of a block group code its minimal trellis can be constructed using the BCJR algorithm. The BCJR based trellis construction is then provided.

Let G be a finite abelian group. The subgroups of Gⁿ are called n length group codes. A group code of length n can be seen as a linear code of length mn over GF(p). Further, a generator matrix Ψ is constructed for such a code using endomorphisms over [symbol] Zₚ. Ψ is a k×n matrix of endomorphisms where ψ_{i,j} represents the i,j'th entry of the matrix such that ψ_{i,j}: [symbol] Zₚ→ [symbol] Zₚ. This generator matrix can be used like the generator matrices of block linear codes over fields for tasks such as generating the codewords, given the information set, etc. This generator matrix can also be used for Massey construction of the minimal Trellis, just like generator matrices for codes over fields.

An (n, k) systematic group code C is a code over Gⁿ of order |G|^{k} defined by n−k homomorphisms {φj}, such that 1≦j≦(n−k). The codewords of C can be written as (x₁, . . . xₖ, φ₁(x₁, . . . , xₖ), φ₂(X₁, . . . , xₖ), . . . , φₙ₋ₖ(x₁, . . . , xₖ)). Here xₖ₊ⱼ=φⱼ(x₁, . . . , xₖ). By the definition of the homomorphism φ, previous expression is rewritten as

xₖ₊ⱼ=⊕_{i≦l≦k}φⱼ(e, . . . , x₁, . . . e) (1)

Since φⱼ(e₁, . . . , x₁, . . . e)εG, φⱼ(e₁, . . . , x₁, . . . e) can be expressed as ψ_{1,j}(x₁), where ψ_{i,j} are endomorphisms over G. Hence,

x_{k+j=⊕}_{i≦l≦k}ψ_{i,j}(xᵢ) (2)

Therefore for systematic codes, the generator matrix can be written as G=[I|k]

$$Ψ = ( \begin{matrix}{Ψ}_{1 , 1} , … , {Ψ}_{1 , n - k} \\ {Ψ}_{2 , 1} , … , {Ψ}_{2 , n - k} \\ ⋮ \\ {Ψ}_{k , 1} , … , {Ψ}_{k , n - k}\end{matrix} ) \qquad ( 3 )$$

Codewords are formed as

(x₁, . . . xₙ)=[x₁, . . . , xₖ]G (4)

Since any finite abelian group can be expressed as G≡C_{d}_{₁} [symbol] C_{d}_{₂} [symbol] . . . C_{d}_{ₘ}1, any element of G can be written in terms of the m generators, {g₁, . . . , gₘ}. Any element of G can be written as

x=⊕_{1≦i≦m}xβ,ᵢgᵢ (5)

Now, consider the endomorphisms ψ_{i,j} themselves, let

ψ(gᵢ)=⊕_{1≦j≦m}α_{i,j}gⱼ (6)

Then, ψ can be written as

$$Ψ = ( \begin{matrix}{α}_{1 , 1} , … , {α}_{1 , m} \\ ⋮ \\ ⋮ \\ {α}_{m , 1} , … , {α}_{m , m}\end{matrix} ) \qquad ( 7 )$$

Thus, using equation (5) and equation (6), ψ(x) can be written as

$$ψ ( x ) = {⊗}_{1 \leq h \leq m} \{ {\sum }_{1 \leq i \leq m} {x}_{β , h} {α}_{i , h} mod {d}_{h} \} {g}_{h} \qquad ( 8 )$$

Given a generator matrix of a group code C, a Theorem 1 helps us construct the generator matrix of the dual code C^{⊥}. This is nothing but the parity check matrix of C. This parity check matrix is used to construct a BCJR trellis for C later in the description.

Massey Construction for Codes Over Finite Abelian Group Codes

Massey construction is a technique for obtaining a minimal trellis for any linear block code over finite fields. The technique is applied herein for finite group codes.

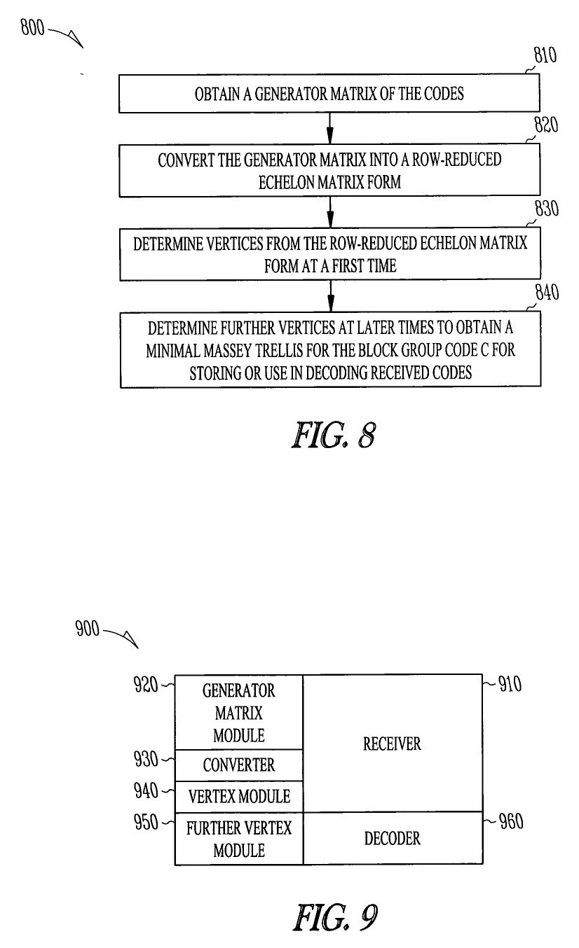

FIG. 8 is a flowchart illustrating a method 800 of constructing a trellis for decoding block group code C. At 810, a generator matrix of the codes is obtained. At 820, the generator matrix is converted into a row-reduced echelon matrix form. Vertices are determined at 830 from the row-reduced echelon matrix form at a first time. Further vertices are determined at 840 at later times to obtain a minimal Massey trellis for the block group code C for storing or use in decoding received codes.

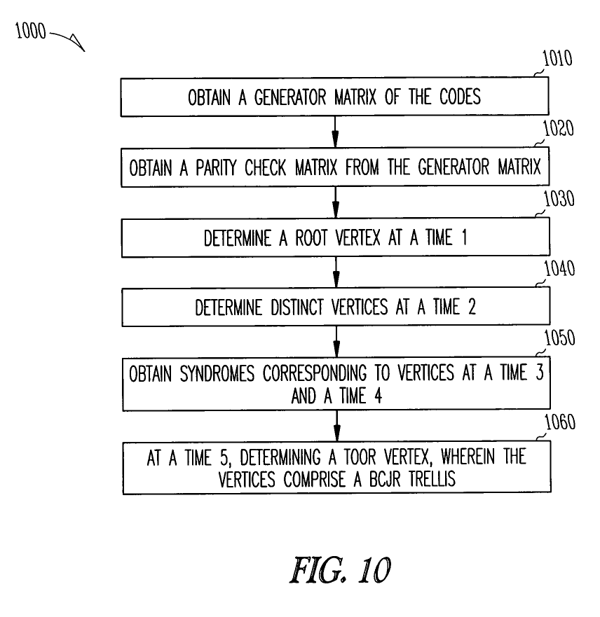

FIG. 9 represents a receiver 910 in one example embodiment. Receiver 910 includes a generator matrix module 920 that obtains a generator matrix of codes corresponding to a block group code C. A converter 930 converts the generator matrix into a row-reduced echelon matrix form. A vertex module 940 determines vertices from the row-reduced echelon matrix form at a first time. A further vertex module 950 determines further vertices at later times to obtain a minimal Massey trellis for the block group code C for storing or use in decoding received codes. In one embodiment, the receiver 910 also includes a decoder 960 that uses the Massey trellis to decode received codes.

Consider an example where p=2 and every element q of G can be written in terms of the products of the underlying elements over GF(2). For example, in a code C={0, x, y, xy}, the elements may be represented in terms of C₂×C₂ as follows

0→(0,0),x→(0,1),y→(1,0),xy→(1,1) (9)

Hence, the 2×2 endomorphisms ψ_{i,j} could be like

$$( \begin{matrix}00 \\ 11\end{matrix} ) .$$

The generator matrix of a (2, 3) code would be of the form

$$Ψ = ( \begin{matrix}( \begin{matrix}00 \\ 11\end{matrix} ) & ( \begin{matrix}01 \\ 01\end{matrix} ) & ( \begin{matrix}11 \\ 01\end{matrix} ) \\ ( \begin{matrix}00 \\ 11\end{matrix} ) & ( \begin{matrix}11 \\ 11\end{matrix} ) & ( \begin{matrix}00 \\ 00\end{matrix} )\end{matrix} ) \qquad ( 10 )$$

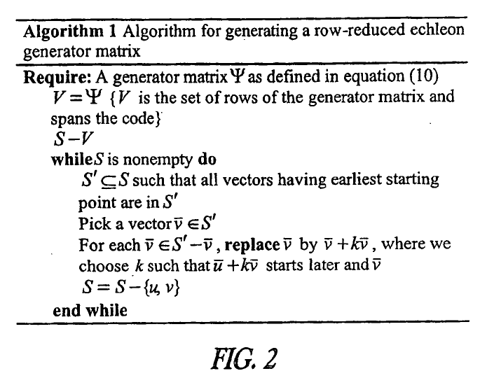

The matrix above could be considered to be a 2k×2n matrix over GF(2) and an algorithm 200 in FIG. 2 may be used to convert it into the row-reduced echleon form which may be used for the Massey construction.

In applying algorithm 200 to the code mentioned above, the generator matrix of the code is as follows (after the various 2×2 endomorphisms are considered as one large matrix:

$$Ψ = ( \begin{matrix}00011110 \\ 01001111 \\ 01100110 \\ 11011011\end{matrix} )$$

Using algorithm 200, a row-reduced echleon matrix is obtained:

$${Ψ}^{′} = ( \begin{matrix}10001010 \\ 01001111 \\ 00101001 \\ 00011110\end{matrix} ) \qquad ( 11 )$$

ψ′, may be used to construct the Massey trellis for it. Let the resulting minimal trellis be T. The starting position of a row x in ψ′ is designated as ↑(x). Further, the columns of ψ′ of weight one are represented as (γ₁, γ₂, . . . γₖ).

Vertices in T at time instant i (represented as Vᵢ) are the equivalence classes represented by (cᵢ₊₁, cᵢ₊₂, . . . cₙ) where

(c₁,c₂, . . . , cₙ)=(a₁,a₂, . . . aₘ,0,0,0)Ψ′

where (a₁, a₂, . . . aₘ) is the set of information symbols of the input such that

m=max{jε(γ₁,γ₂, . . . γₖ):j≦i}

Or

Vᵢ≅(cᵢ₊₁,cᵢ₊₂, . . . cₙ) (12)

For the trellis, beginning the initial vertex φ called the root vertex of T at time 0, the equivalence classes at time 1 are

(0000)Ψ′=(0000000)

(1000)Ψ′=(0001010)

Hence there will be two vertices. The equivalence classes at later times are shown below. At time 2,

(0000)Ψ′=(000000)

(0100)Ψ′=(001111)

(1000)Ψ′=(001010)

(1100)Ψ′=(000101)

and so on. The resulting trellis 100 obtained is as shown in FIG. 1. Clearly, this is isomorphic to a KS trellis construction.

Proof that Massey Construction Produces the Minimal Trellis

THEOREM III.1. The Massey construction as per algorithm 200 is minimal

Proof: We will prove that the resulting Massey trellis over a group is two way proper, which is sufficient to prove it is minimal. First we prove the forward proper property.

Let T be a Massey Trellis for a code C. Let γₘ=i. Let aₘ be the m'th information symbol. The states in the Massey trellis are the equivalence classes represented by

Vᵢ≡(a₁, . . . , aₘ,0, . . . , 0)G_{k×(m+1,n)} (13)

Where G_{k×(m+1,n)} represents the k rows and the columns m+1, . . . , n of the generator matrix G. Consider a particular vertex vεVᵢ₋₁ in T. It can be represented as a₁, . . . , aₘ₋₁, 0, . . . , 0)G_{k×(m+1,n)} for some fixed a₁, . . . , aₘ₋₁. the vertex v can be represented by the sum Σ_{i-1≦j≦n}Σ_{1≦k≦m-1}c_{j,k}aₖ, where c_{m,n} represents the element in the m′th column and n'th row of G. For this codeword to reach a vertex in the i'th section of the trellis, another information symbol is to be added and the information set becomes (a₁, . . . , aₘ₋₁,x). The vertex v′εVᵢ₊₁ corresponding to these information symbols can be represented as v′=Σ_{i-1≦j≦n}Σ_{1≦k≦m-1}c_{j,k}aₖ+xΣ_{i+1≦j≦n}c_{m,j}. Clearly, for different values of x, the sum will be different and hence the trellis is forward proper.

The reverse case may now be proved. Consider two distinct vertices v and v′εVᵢ represented by (a₁, . . . , aₘ,0, . . . , 0)G_{k×i+1,n} and (a₁′, . . . , aₘ′,0, . . . , 0)G_{k×i+1,n}. Let v″εVᵢ₊₁ such that codewords from v and v′ converge at v″. Then, since no additional information symbol is introduced at the i+1'th section, the sums of both information sets must be the same as shown below at the i+1'th section of the trellis. This means that (a₁, . . . aₘ, 0, . . . , 0) G_{k×i+2,n}=(a₁′, . . . , aₘ′, 0, . . . , 0)G_{k×i+2,n}. However, the sums are different at the i'th section which means that (a₁, . . . , aₘ, 0, . . . 0)G_{k×i+1,n}=(a₁′, . . . aₘ′, 0, . . . , 0)G_{k×i+1,n}

Expanding these two conditions:

$${\sum }_{i + 1 \leq j \leq n} {\sum }_{1 \leq k \leq m} {c}_{j , k} {a}_{k}^{′} \neq {\sum }_{i + 1 \leq j \leq n} {\sum }_{1 \leq k \leq n} {c}_{j , k} {a}_{k}$$

$${\sum }_{i + 2 \leq j \leq n} {\sum }_{1 \leq k \leq m} {c}_{j , k} {a}_{k}^{′} \neq {\sum }_{i + 2 \leq j \leq n} {\sum }_{1 \leq k \leq m} {c}_{j , k} {a}_{k}$$

The above two equations imply that

$${\sum }_{1 \leq k \leq m} {c}_{i + 1} {a}_{k} \neq {\sum }_{1 \leq k \leq m} {c}_{i + 1} {a}_{k}^{′}$$

The LHS and RHS of the above equations are the edge labels from vertex v to v″ and v′ to v″ respectively. Hence, all converging states have distinct labels, which completes the proof that the trellis is proper in the reverse case.

BCJR Trellis for Group Codes

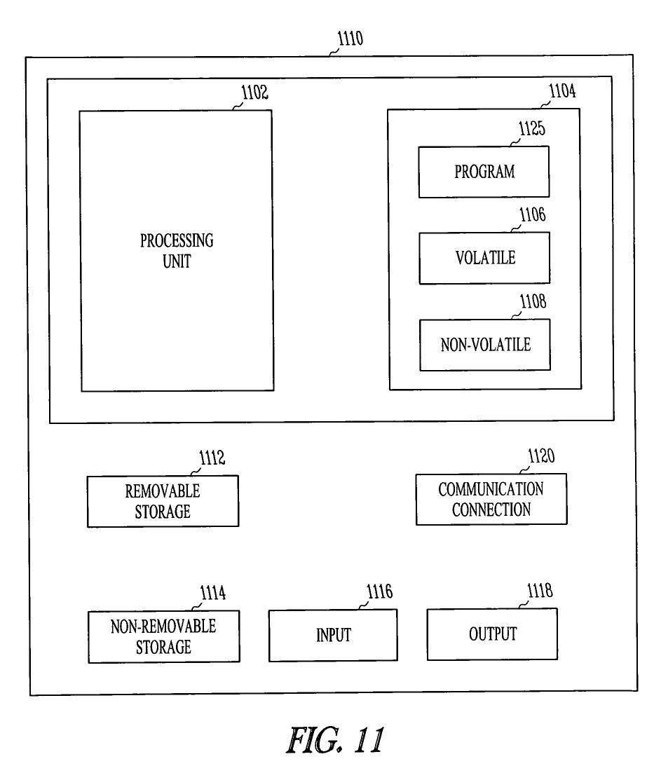

An alternative method 1000 in FIG. 10 constructs a trellis for decoding block group code C. At 1010, a generator matrix of the codes is obtained. At 1020, a parity check matrix is derived from the generator matrix. At 1030, a root vertex at a time 1 is determined. At 1040, distinct vertices at a time 2 are determined. Syndromes corresponding to vertices at a time 3 and a time 4 are then obtained at 1050, and at a time 5, a toor vertex is determined at 1060, wherein the vertices comprise a BCJR trellis.

An algorithm for constructing the minimal trellis for a linear block code over GF(p) is extended for construction of group codes over Finite Abelian groups. The purpose of any technique for constructing a minimal trellis is to determine the set of vertices at time i in the trellis (denoted by Vᵢ). Let Pᵢ−(C) represent the codeword pasts, where C is a linear block code of length n and 1≦≦n. Let H be the parity check matrix of the code C.

According to [1], if cεPᵢ−(C), then the equivalence classes formed by the syndrome Hc^{T} represents the future equivalences, Vᵢ. In one example, consider a (4, 2) group code over C₂² with the generator matrix (equation 14) and parity check matrix (equation 15). A minimal trellis is constructed for this code using the BCJR technique.

$$\begin{matrix}G = ( \begin{matrix}( \begin{matrix}10 \\ 01\end{matrix} ) & ( \begin{matrix}00 \\ 00\end{matrix} ) & ( \begin{matrix}11 \\ 01\end{matrix} ) & ( \begin{matrix}11 \\ 01\end{matrix} ) \\ ( \begin{matrix}00 \\ 00\end{matrix} ) & ( \begin{matrix}10 \\ 01\end{matrix} ) & ( \begin{matrix}11 \\ 01\end{matrix} ) & ( \begin{matrix}01 \\ 10\end{matrix} )\end{matrix} ) & ( 14 ) \\ H = ( \begin{matrix}( \begin{matrix}10 \\ 11\end{matrix} ) & ( \begin{matrix}10 \\ 11\end{matrix} ) & ( \begin{matrix}10 \\ 01\end{matrix} ) & ( \begin{matrix}00 \\ 00\end{matrix} ) \\ ( \begin{matrix}10 \\ 11\end{matrix} ) & ( \begin{matrix}01 \\ 10\end{matrix} ) & ( \begin{matrix}00 \\ 00\end{matrix} ) & ( \begin{matrix}10 \\ 01\end{matrix} )\end{matrix} ) & ( 15 )\end{matrix}$$

Instead of the usual code alphabet, the matrices G and H above consist of 2×2 matrices which, are endomorphisms as required by equation (3). A BCJR trellis is constructed over the above code. Looking at C₂²={00, 01, 10, 11}, it is observed that it is generated by the vectors g₁=01 and g₂=10. Or,

<g₁,g₂>=C₂²

### Hence,

00=g₁⁰g₂⁰
01=g₁¹g₂⁰
10=g₁⁰g₂¹
11=g₁¹g₂¹

There is one vertex at time i=1 and is called the root vertex. To see how many vertices there are, at i=2, the syndromes H₁p₁^{T} are calculated:

$${{H}_{1} ( 00 )}^{T} = ( \begin{matrix}00 \\ 00\end{matrix} ) , {{H}_{1} ( 10 )}^{T} = ( \begin{matrix}10 \\ 10\end{matrix} )$$

$${{H}_{1} ( 01 )}^{T} = ( \begin{matrix}11 \\ 11\end{matrix} ) , {{H}_{1} ( 11 )}^{T} = ( \begin{matrix}01 \\ 01\end{matrix} )$$

which leads to the conclusion that there are four distinct vertices at time i=2.

Similarly, at i=3, calculate the syndromes) H₃p₃^{T}. The following syndromes are obtained:

$${{H}_{2} ( 0000 )}^{T} = ( \begin{matrix}00 \\ 00\end{matrix} ) , {{H}_{2} ( 0001 )}^{T} = ( \begin{matrix}11 \\ 10\end{matrix} )$$

$${{H}_{2} ( 0010 )}^{T} = ( \begin{matrix}10 \\ 01\end{matrix} ) , {{H}_{2} ( 0011 )}^{T} = ( \begin{matrix}01 \\ 11\end{matrix} )$$

$${{H}_{2} ( 0100 )}^{T} = ( \begin{matrix}11 \\ 11\end{matrix} ) , {{H}_{2} ( 0101 )}^{T} = ( \begin{matrix}00 \\ 01\end{matrix} )$$

$${{H}_{2} ( 0110 )}^{T} = ( \begin{matrix}01 \\ 10\end{matrix} ) , {{H}_{2} ( 0111 )}^{T} = ( \begin{matrix}10 \\ 00\end{matrix} )$$

$${{H}_{2} ( 1000 )}^{T} = ( \begin{matrix}10 \\ 10\end{matrix} ) , {{H}_{2} ( 1001 )}^{T} = ( \begin{matrix}01 \\ 00\end{matrix} )$$

$${{H}_{2} ( 1010 )}^{T} = ( \begin{matrix}00 \\ 11\end{matrix} ) , {{H}_{2} ( 1011 )}^{T} = ( \begin{matrix}11 \\ 01\end{matrix} )$$

$${{H}_{2} ( 1100 )}^{T} = ( \begin{matrix}01 \\ 01\end{matrix} ) , {{H}_{2} ( 1101 )}^{T} = ( \begin{matrix}10 \\ 11\end{matrix} )$$

$${{H}_{2} ( 1110 )}^{T} = ( \begin{matrix}11 \\ 00\end{matrix} ) , {{H}_{2} ( 1111 )}^{T} = ( \begin{matrix}00 \\ 10\end{matrix} )$$

Clearly, all 16 syndromes are distinct and there are 16 vertices at this stage of the trellis.

At time i=4, the following syndromes are obtained

$${{H}_{2} ( 000000 )}^{T} = ( \begin{matrix}00 \\ 00\end{matrix} ) , {{H}_{2} ( 001010 )}^{T} = ( \begin{matrix}00 \\ 01\end{matrix} )$$

$${{H}_{2} ( 000111 )}^{T} = ( \begin{matrix}00 \\ 10\end{matrix} ) , {{H}_{2} ( 001101 )}^{T} = ( \begin{matrix}00 \\ 11\end{matrix} )$$

$${{H}_{2} ( 100010 )}^{T} = ( \begin{matrix}00 \\ 10\end{matrix} ) , {{H}_{2} ( 101000 )}^{T} = ( \begin{matrix}00 \\ 11\end{matrix} )$$

$${{H}_{2} ( 100101 )}^{T} = ( \begin{matrix}00 \\ 00\end{matrix} ) , {{H}_{2} ( 101111 )}^{T} = ( \begin{matrix}00 \\ 01\end{matrix} )$$

$${{H}_{2} ( 010010 )}^{T} = ( \begin{matrix}00 \\ 11\end{matrix} ) , {{H}_{2} ( 011001 )}^{T} = ( \begin{matrix}00 \\ 10\end{matrix} )$$

$${{H}_{2} ( 010100 )}^{T} = ( \begin{matrix}00 \\ 01\end{matrix} ) , {{H}_{2} ( 011110 )}^{T} = ( \begin{matrix}00 \\ 00\end{matrix} )$$

$${{H}_{2} ( 110001 )}^{T} = ( \begin{matrix}00 \\ 01\end{matrix} ) , {{H}_{2} ( 111011 )}^{T} = ( \begin{matrix}00 \\ 00\end{matrix} )$$

$${{H}_{2} ( 110110 )}^{T} = ( \begin{matrix}00 \\ 11\end{matrix} ) , {{H}_{2} ( 111100 )}^{T} = ( \begin{matrix}00 \\ 10\end{matrix} )$$

From the above syndromes, it is seen that there are four vertices at this stage of the trellis with syndromes

$$( \begin{matrix}00 \\ 00\end{matrix} ) , ( \begin{matrix}00 \\ 01\end{matrix} ) , ( \begin{matrix}00 \\ 10\end{matrix} ) , and ( \begin{matrix}00 \\ 11\end{matrix} ) .$$

At time i=5, p₄ will constitute of codewords from C and hence all the syndromes will be

$$( \begin{matrix}00 \\ 00\end{matrix} )$$

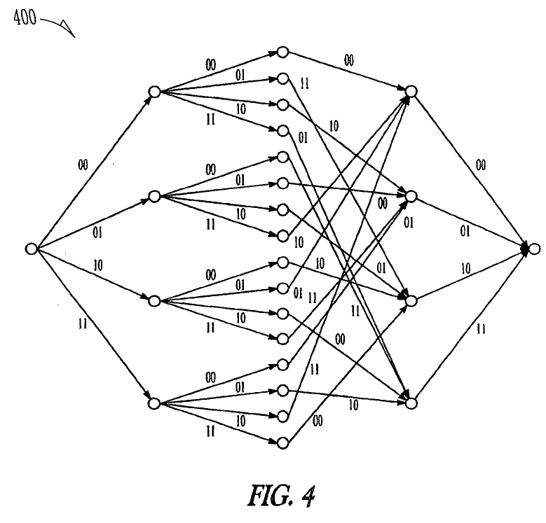

(null vector) by definition. This single vertex at this stage of the trellis is called the toor. FIG. 4 illustrates this minimal trellis 400.

Proof of Minimality of the Proposed BCJR Technique

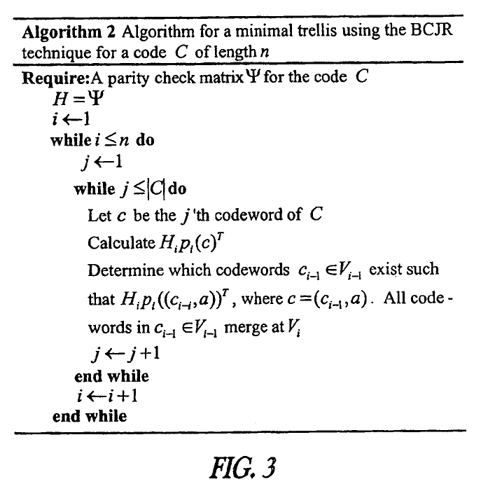

THEOREM IV.1. The Trellis created by algorithm 300 in FIG. 3 is minimal.

Proof The proof of minimality is similar to the proof of minimality of a BCJR trellis over a finite field. The concepts of ˜_{T} equivalence (denoted as ˜_{T}) and future equivalence (denoted as ˜) are used.

Let c₁, c₂εC, where C is a length n linear block code. For some iε[1, n], if Pᵢ(c₁)˜_{T}Pi(c₂), then it always follows that Pᵢ(c₁)˜Pi(c₂). For a minimal trellis, the reverse also holds true, i.e. Pᵢ(c₁)˜Pi(c₂) always implies that Pᵢ(c₁)˜_{T}Pi(c₂). Given codewords c, c′εC such that c=(c₁, c₂, . . . , cₙ) and c′=(c′₁, c′₂, . . . , c′ₙ), we have

$$\begin{matrix}{c}_{1} {H}_{1} + {c}_{2} {H}_{2} … + {c}_{n} {H}_{n} = ( \begin{matrix}00 \\ 00\end{matrix} ) & ( 16 ) \\ {c}_{1}^{′} {H}_{1} + {c}_{2}^{′} {H}_{2} … + {c}_{n}^{′} {H}_{n} = ( \begin{matrix}00 \\ 00\end{matrix} ) & ( 17 )\end{matrix}$$

If c and c′ are future equivalent at time i, they must share a common future after the i'th section of the trellis. Let that common future be x=xᵢ₊₁, . . . xₙ. Then, H (Pᵢ(c),x)=H(Pᵢ(c′),x), which means that

c₁H₁+ . . . +cᵢHᵢ=−(xᵢ₊ᵢHᵢ₊₁+ . . . +xₙHₙ)

which in turn is equal to c₁′H₁+ . . . +cᵢ′Hᵢ. Both the above equations imply that c and c′ are T-equivalent at some vertex of the trellis at section i. Hence, future equivalence implies T-equivalence, completing the proof.

The task of Minimal Trellis construction includes

1) Conversion of whichever matrix is used for the construction to a desired form. This includes converting a generator matrix to a two-way proper form for the KS method, a row-reduced echleon format for the Massey method etc.
2) Obtaining the number of vertices (represented as |Vᵢ(T)|) in each section of the trellis.
3) Determining the edge transitions between states of the trellis (E(T)).
It is assumed throughout the section that the computation (group operation in one embodiment) takes a unit amount of computing power.

Since any parity check matrix can be used for calculating the syndromes HᵢCᵢ^{T}, the complexity of matrix conversion is Zero.

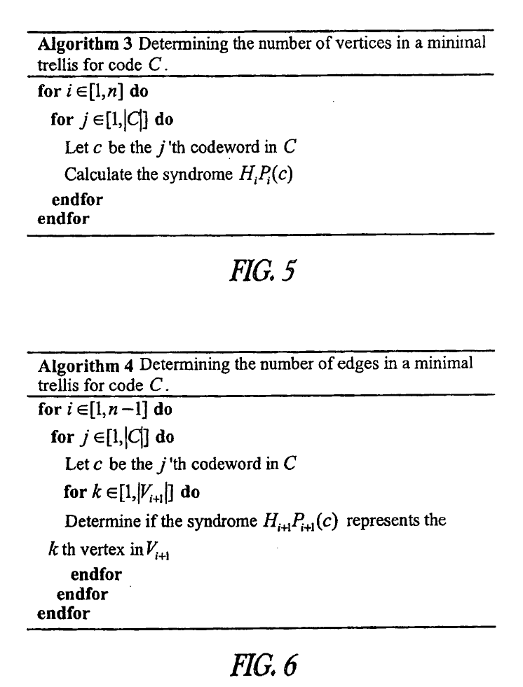

To determine the number of vertices in the minimal trellis at any time, all the syndromes are calculated. Algorithm 500 in FIG. 5 shows one example method. The complexity of this task is |C|n. The complexity of determining the edge transitions in this minimal trellis whose vertex set V(T) is known by the previous algorithm 300. The complexity is shown in algorithm 600 in FIG. 6. Algorithm 600 is of complexity

Σ_{1≦i≦n}n|C|Vᵢ₊₁|,≈n|C∥V(T)|

The generator matrix for the Massey Trellis may be reduced to the row reduced echleon form. This is bounded by O(k²n). The task of determining the vertex sets and edge transitions is the same as for a BCJR trellis as both these techniques rely on calculating syndromes.

The generator matrix for the KS Trellis is bounded by O(k²n). Let the group G from which the code is generated be isomorphic to Z_{q}. The number of vertices at the i'th time instant in the KS trellis is q^{ri}, where rᵢ is the number of rows active at time i. The algorithm which keeps track of how many rows are active at time i in a generator matrix is of order O(kn).

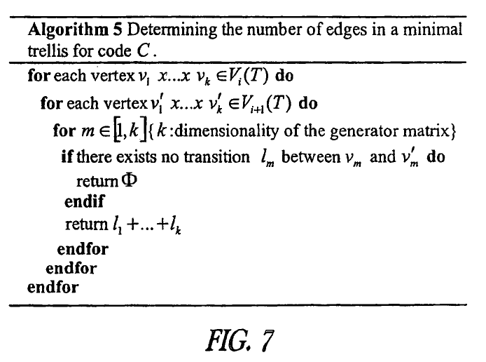

Every vertex in the KS trellis at time i can be written as v₁× . . . ×vₖ, where vᵢ belongs to the minimal trellis formed by the i'th row alone. This is because the KS trellis is a product trellis. Similarly, every vertex at time i+1 can be written as v₁′× . . . ×vₖ′. An algorithm 700 in FIG. 7 determines the edge transitions in this trellis. The complexity of the algorithm 700 is

$${\sum }_{1 \leq i \leq n - 1} k \vert {V}_{i} \vert \vert {V}_{i + 1} \vert$$

In various embodiments, the BCJR technique of trellis generation may be done without manipulation of the parity check matrix before being used for trellis construction. This is not the case for Massey and KS techniques. This makes the BCJR technique computationally attractive when compared to the other techniques. For high rate codes, the parity check matrices are sparse and the BCJR technique is more computationally efficient as it uses a parity check matrix rather than using a generator matrix.

A block diagram of a computer system that may be used to execute programming for performing the above algorithms is shown in FIG. 11. A general computing device in the form of a computer 1110, may include a processing unit 1102, memory 1104, removable storage 1112, and non-removable storage 1114. Memory 1104 may include volatile memory 1106 and non-volatile memory 1108. Computer 1110 may include—or have access to a computing environment that includes—a variety of computer-readable media, such as volatile memory 1106 and non-volatile memory 1108, removable storage 1112 and non-removable storage 1114. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 1110 may include or have access to a computing environment that includes input 1116, output 1118, and a communication connection 1120. The computer may operate in a networked environment using a communication connection to connect to one or more remote computers. The remote computer may include a personal computer (PC), server, router, network PC, a peer device or other common network node, or the like. The communication connection may include a Local Area Network (LAN), a Wide Area Network (WAN) or other networks.

Computer-readable instructions stored on a computer-readable medium are executable by the processing unit 1102 of the computer 1110. A hard drive, CD-ROM, and RAM are some examples of articles including a computer-readable medium.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A method of constructing a trellis for decoding block group code C, the method comprising:
obtaining a generator matrix of the codes;
converting the generator matrix into a row-reduced echelon matrix form;
determining vertices from the row-reduced echelon matrix form at a first time; and
determining further vertices at later times to obtain a minimal Massey trellis for the block group code C for storing or use in decoding received codes.

2. The method of claim 1 wherein the block group codes comprises a finite abelian group.

3. The method of claim 1 wherein the Massey trellis is obtained for a linear block code over finite fields.

4. The method of claim 1 wherein the vertices are equivalence classes.

5. The method of claim 1 and further comprising using the Massey trellis to decode received codes.

6. The method of claim 1 wherein the Massey trellis is constructed at a receiver.

7. A receiver comprising:
means for obtaining a generator matrix of codes corresponding to a block group code C;
means for converting the generator matrix into a row-reduced echelon matrix form;
means for determining vertices from the row-reduced echelon matrix form at a first time; and
means for determining further vertices at later times to obtain a minimal Massey trellis for the block group code C for storing or use in decoding received codes.

8. The receiver of claim 7 wherein the block group codes comprises a finite abelian group.

9. The receiver of claim 7 wherein the Massey trellis is obtained for a linear block code over finite fields.

10. The receiver of claim 7 wherein the vertices are equivalence classes.

11. The receiver of claim 7 and further comprising a module that uses the Massey trellis to decode received codes.

12. A machine readable medium having instructions for execution by a system for performing a method comprising:
obtaining a generator matrix of codes corresponding to a block group code C;
converting the generator matrix into a row-reduced echelon matrix form;
determining vertices from the row-reduced echelon matrix form at a first time; and
determining further vertices at later times to obtain a minimal Massey trellis for the block group code C for storing or use in decoding received codes.

13. The machine readable medium of claim 11 wherein the block group codes comprises a finite abelian group.

14. The machine readable medium of claim 11 wherein the Massey trellis is obtained for a linear block code over finite fields.

15. The machine readable medium of claim 11 wherein the vertices are equivalence classes.

16. The machine readable medium of claim 11 wherein the method further comprising using the Massey trellis to decode received codes.

17. The machine readable medium of claim 11 wherein the Massey trellis is constructed at a receiver.

18. (canceled)
